(19) United States
(12) Patent Application Publication
(10) Pub. No.: US 2024/0143861 A1
(43) Pub. Date: May 2, 2024

(54) ACTOR-BASED DISTRIBUTION COMPUTATION FOR PARTITIONED POWER SYSTEM SIMULATION

(71) Applicant: X Development LLC, Mountain View, CA (US)

(72) Inventors: Mike Miao He, Mountain View, CA (US); Leo Francis Casey, San Francisco, CA (US); Hamed Khalilinia, San Mateo, CA (US)

(21) Appl. No.: 17/977,430

(22) Filed: Oct. 31, 2022

(51) Int. Cl. G06F 30/20

(52) U.S. Cl. CPC G06F 30/20

(57) ABSTRACT

Methods, systems, and apparatus, including computer programs encoded on a computer storage medium, for obtaining a model of an electrical power system including multiple subcircuits. Assigning each of multiple subcircuits to a processing core from among multiple processing cores employed for simulation of the model; executing a simulation of electric grid behaviors of the model, where the simulation of each subcircuit can be executed by the respective processing core assigned to the subcircuit. Sending a message, from a first processing core assigned to a first subcircuit to a second processing core assigned to a second subcircuit, the message including one or more boundary conditions at an interface between the first subcircuit and the second subcircuit in the model.

### TECHNICAL FIELD

The present specification relates to electrical power grids, and specifically to performing an electrical behavior simulation of an electrical grid model.

### BACKGROUND

Electrical power grids transmit electrical power to loads such as residential and commercial buildings. Virtual models of an electrical grid can be used to simulate operations under various conditions. The complexity of modern electric grids due to increased use and distribution of renewable energy sources necessitates increased complexity in electric grid models and simulations. New simulation processes are needed in order to accurately and efficiently simulate such complex models.

### SUMMARY

Current approaches for modeling the electric grid do not scale well for large-scale simulations. Partitioning the power system into multiple subcircuits and simulating operations of each subcircuit on different machines can alleviate this scaling issue. Disclosed herein is an electrical power grid interconnection simulation system that can utilize actor-based distributed computation to partition models of an electrical power system. A simulation system can partition a model of an electric power system and then simulate the subcircuits in parallel and distributed across different machines and/or processor cores. The simulation process can employ a messaging system to synchronize the individual simulations of each subcircuit to the larger simulation of the full power system.

A messaging system can pass boundary conditions between different machines and/or processing cores executing simulations for neighboring subcircuits. The messaging system accounts for the effects of each individual subcircuit on its neighboring subcircuits and coordinates the overall grid simulation between the individual machines and/or processing cores. For example, a message could include the current, voltage, and simulation time step. There are various ways in which the individual machines and/or processing cores can react to the messages. In some implementations, each individual subcircuit simulation could run up to a point in time until the subcircuit receives a message from all its neighboring subcircuits with an appropriate simulation time step. After receiving the message and parsing its contents, the simulation can advance in time. In some implementations, time-based multiplexing can reduce the need to wait for neighboring subcircuits to send messages with the appropriate simulation time step. The simulation system can use a coarser time resolution for all subcircuits, but when there is a transient event that triggers the need for more detail (e.g., receipt of a message related to a neighboring subcircuit), the relevant machine/processing core can correct past values by simulating its respective subcircuit. In some implementations, the relevant processing core can reduce the simulation time step size to be closer to the appropriate time step size used to simulate the transient event. In some implementations, predictive algorithms or extrapolation can allow an individual subcircuit to advance in time before it has received a message from a neighboring subcircuit with an appropriate simulation time step.

By dividing the power system into subcircuits, each subcircuit can operate at conditions that are suitable for its electrical components. For example, subsystems with transient phenomena can use finer time resolutions, while subsystems with slower-acting or passive components can use coarser time resolutions. Phasor type simulations could apply to subcircuits with passive elements, while time domain-simulations could be suitable for other subcircuits.

A simulation system can divide a model of an electrical grid into subcircuits by exploiting electrical propagation delays between various portions of the grid. For example, the model can be divided into subcircuits at locations (e.g., edges) that include relatively long transmission lines, and hence, long propagation delays. Such locations are prime for such divisions because the relative interactions between adjacent subcircuits are delayed. Thus, the simulation system can send messages to the corresponding machines/processing cores in between simulation time steps, given the time step size is small enough. In some implementations, subcircuit divisions are determined based on a combination of the time resolution being used for simulation and the propagation delays between regions in the grid model. The simulation system can divide the electrical grid model into more subcircuits when using smaller time step sizes, as longer propagation delays become exploitable for message passing.

In general, innovative aspects of the subject matter described in this specification can be embodied in methods that include the actions of obtaining a model of an electrical system including a plurality of subcircuits, assigning each of the plurality of subcircuits to a processing core from among a plurality of processing cores employed for simulation of the model, executing a simulation of behaviors of the model, wherein the simulation of each subcircuit is executed by the respective processing core assigned to the subcircuit, and sending a message, from a first processing core assigned to a first subcircuit to a second processing core assigned to a second subcircuit, the message including one or more boundary conditions at an interface between the first subcircuit and the second subcircuit in the model. Other implementations of this aspect include corresponding systems, apparatus, and computer programs, configured to perform the actions of the methods, encoded on computer storage devices.

These and other implementations can each optionally include one or more of the following features.

Some implementations include evaluating one or more electrical components in the model of the electrical system, and based on the evaluation of the one or more electrical components in the model of the electrical system, partitioning the model into the plurality of subcircuits.

Some implementations include determining one or more propagation delays between the plurality of subcircuits, where partitioning the model into the plurality of subcircuits is further based on the one or more propagation delays between the plurality of subcircuits.

In some implementations, evaluating one or more electrical grid components in the model of the electrical system includes determining a simulation time step size associated with one or more of the electrical grid components in the model of the electrical power system.

In some implementations, executing the simulation of electric grid behaviors of the model includes: executing the simulation of the first subcircuit on by the first processing core according to a first set of simulation parameters, and executing the simulation of the second subcircuit on the second processing core according to a second, different set of simulation parameters.

In some implementations, the first set of simulation parameters includes a first simulation time step size and the second set of simulation parameters includes a second, different simulation time step size.

In some implementations, the one or more boundary conditions of the first subcircuit include simulation output, generated by the first processing core, for electrical conditions at the interface.

In some implementations, the electrical conditions include one or more of: a current value at the interface, a voltage value at the interface, a simulation time step at which the current and voltage values were simulated, and a propagation delay between the first subcircuit and the second subcircuit.

In some implementations, executing a simulation of the behaviors of the model include: completing a simulation of the first subcircuit up until a simulation time step tₙ, wherein the message includes boundary conditions at the interface between the first subcircuit and the second subcircuit at simulation time step tₙ, and in response to receiving the message, executing, by the second processing core, simulation of electric grid behaviors of the model in the second subcircuit for simulation time step tₙ₊₁.

In some implementations, each subcircuit of the plurality of subcircuits has a default time step size, and the method includes: identifying a transient behavior in the first subcircuit at a simulation time step tₙ, reducing, by the first processor, a time step size of the first subcircuit to less than the default time step size, and continuing to execute simulation of the first subcircuit with the reduced time step size and the second subcircuit with the default time step size for simulation time steps greater than simulation time step tₙ.

Some implementations include sending, to the second processing core, a second message, indicating boundary conditions at the interface between the first subcircuit and the second subcircuit and an indication that a time step size in the first subcircuit is less than a default time step size, at a simulation time step tₙ₊₁ greater than the simulation time step tₙ, and receiving, from the first processing core, the second message.

Some implementations include calculating, by the second processing core, values for the interface at the simulation time step tₙ₊₁, in response to receiving the second message, determining, by the first processing core, that the second message includes values for the boundary conditions at the interface that disagree with the calculated values outside a threshold value, and calculating, by the second processing core, a correction factor for simulation of the second subcircuit for the simulation time step tₙ₊₁.

Some implementations include, in response to determining that the second message includes values that disagree with the calculated values outside a threshold value, reducing a time step size of the second subcircuit.

In some implementations, executing a simulation of the behaviors of the model includes: completing a simulation of the first subcircuit up until a simulation time step tₙ₋₁, wherein the message includes boundary conditions at the interface at the simulation time step tₙ₋₁, in response to receiving the message includes the simulation time step tₙ₋₁, estimating, by the second processing core, values for the boundary conditions at the interface at a simulation time step tₙ in the first subcircuit, and continuing to execute, using the estimated values, simulation the first subcircuit for simulation time steps greater that tₙ.

Implementations of the disclosed concepts and ideas can provide one or more of the following advantages. For example, by dividing the system into multiple subcircuits, the simulation system can parallelize the simulations of subcircuits, resulting in a shorter duration of calculation. Further, subcircuits with transient phenomena that require relatively more computational resources can be simulated with appropriate conditions, such as increased time resolution, while the remaining subcircuits can be simulated with coarser conditions. This can reduce the overall computational resources and duration of the simulation, while still providing more accurate and comprehensive simulation results.

### DESCRIPTION OF DRAWINGS

FIGS. 1A and 1B are schematics of an example electrical power system divided into different subcircuits.

FIG. 2 is an example messaging system communicating between different subcircuits.

FIG. 3 is a flowchart of an example process for simulating an electrical power system with subcircuits.

FIG. 4 is a flowchart of an example process for assigning each subcircuit to a processing core.

Throughout the drawings, reference numbers may be re-used to indicate correspondence between reference elements. Like symbols denote similar elements. The drawings are provided to illustrate example embodiments described herein and are not intended to limit the scope of the disclosure.

### DETAILED DESCRIPTION

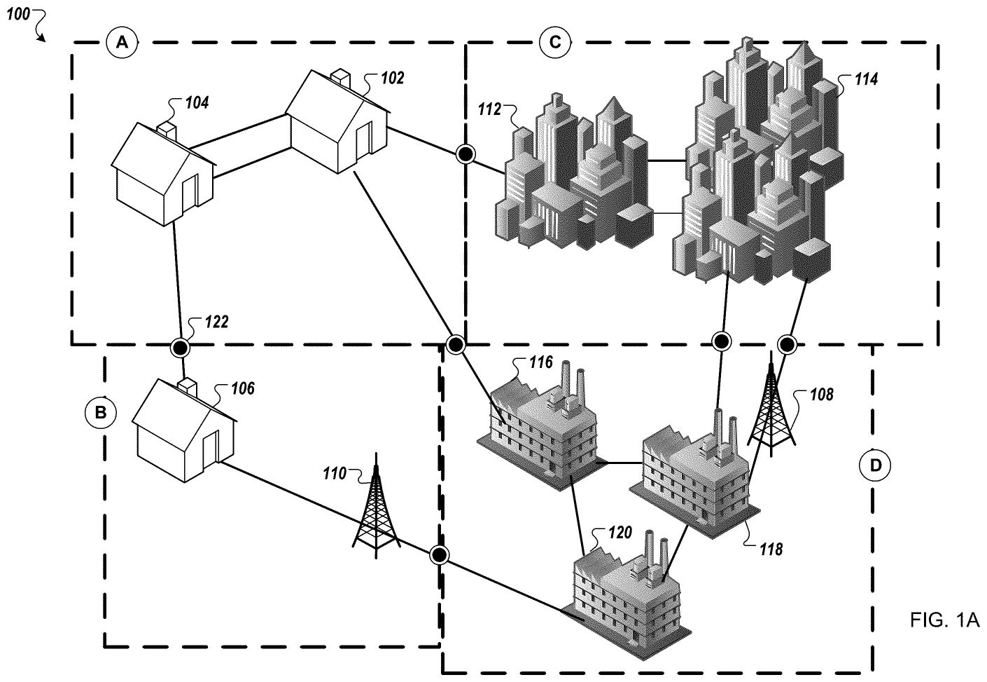

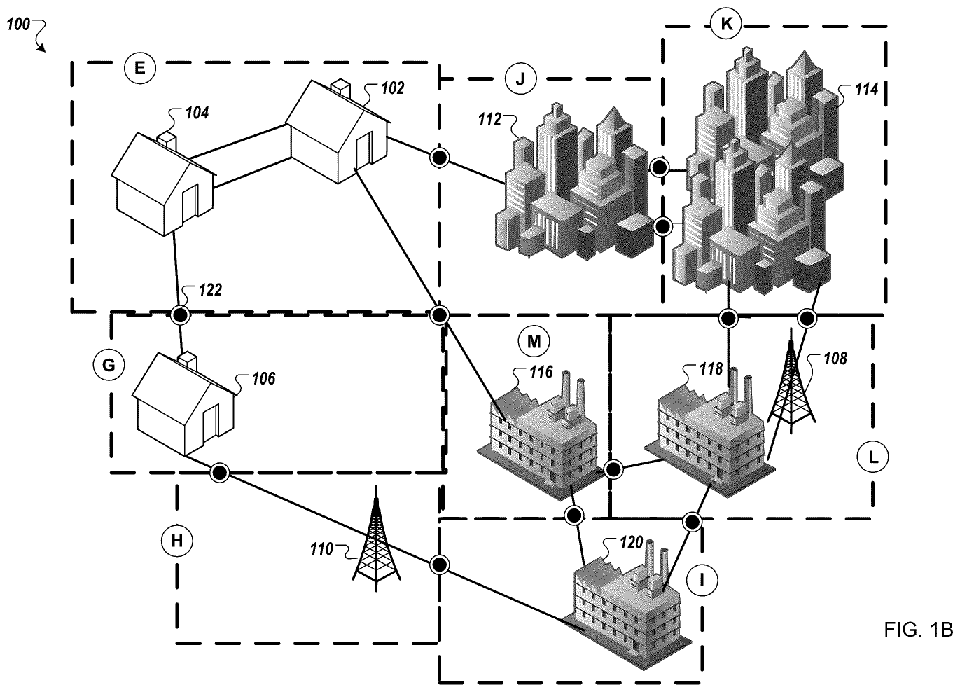

FIG. 1A shows an example model of an electrical power system 100 for a city, suburbs, an industrial zone, and infrastructure. The electrical power system 100 can include residential neighborhoods 102, 104, and 106, substations 108 and 110, city blocks 112 and 114, and power generators 116, 118, and 120. Each of the components in the electrical power system 100 can have unique electrical properties including, but not limited to, effective resistance, impedance, capacitance, inductance, and power capacity. Without subscribing to any particular theory, a simulation system can simulate a model of the electrical power system 100 as an electrical circuit. Every point in a circuit can have a value of current. Between two points in a circuit there can be a potential difference, e.g., a voltage. The simulation system can determine the voltage between any point in the model of the electrical power system 100 and ground, giving a relative voltage at any point in the circuit. In this disclosure, “voltage” will refer to the potential difference between a point in the model of the electrical power system 100 and ground. Both the current and voltage can be a function of time in a circuit, e.g., the current and voltage can change over time.

An electric circuit, e.g., the “grid”, can connect the various components and be organized in way to safely and reliably supply electrical power throughout the electrical power system 100. Transmission lines, represented by solid lines in FIGS. 1A and 1B, can connect the various components so that electricity can flow from one location to another.

A simulation system can include one or more computers, e.g., servers, with memory, data sources, e.g., databases, user devices that provide a user interface, and a network interface that allows communication between the user interface and the computers. In an example scenario, a user device can send a simulation request for simulation results to a simulation server, e.g., over a network. The simulation request includes the parameters input by the user, e.g., the location, scenario, data source, filters, and requested output. In some implementations, the model is stored in a database that is accessible to the simulation server.

The simulation system can partition the grid model into individual subcircuits that can be simulated separately. The model can be partitioned with the condition that relevant electrical values at the boundaries of the subcircuits agree. For example, a simulation system can divide the grid model of the electrical power system 100 into four subcircuits. A dashed line with a letter label marks the boundaries the subcircuits. Subcircuit A includes neighborhoods 102 and 104, subcircuit B includes neighborhood 106 and infrastructure such as substation 110, subcircuit C includes a city with city blocks 112 and 114, and subcircuit D is an industrial zone including power generators 116, 118, and 120 and substation 108.

A simulation system can simulate each subcircuit independently. For example, given the appropriate parameters, the simulation system can calculate the current and voltage in a subcircuit as a function of time. Some transmission lines intersect the boundaries of the four subcircuits. At these interfaces 122, labeled by black circles, the simulation system can calculate values for the current and voltage at the interface in both subcircuits, e.g., the boundary conditions of each subcircuit. At the interfaces 122, the simulation system can model the transmission lines as being split, with equivalent current sources on each side.

The simulation system determines each subcircuit A, B, C, and D, each with its own set of simulation parameters. For example, the simulation system can simulate subcircuit A with a phasor type model using a time step size, e.g., resolution, of 5 seconds, while subcircuit D could be simulated with a time domain type model using a time step size of 5 milliseconds.

The simulation system can determine where to create the boundaries of the subcircuits A, B, C, and D to ensure that the simulation in each neighboring subcircuit will yield the same values for the current and voltage within a threshold value, e.g., the boundary conditions will agree within a threshold value. Subcircuits are considered neighboring if they share an electrical interface, e.g., a transmission line passes from one subcircuit into another. An interface 122 marks where a transmission line passes from one subcircuit to a neighboring subcircuit.

Various factors can impact how the simulation system can select subcircuit boundaries. For example, the simulation system can determine the boundaries of subcircuits based on the type of components, e.g., neighborhoods, city blocks, power plants, and substations, and their locations. In some implementations, the simulation system can determine to partition the grid model of the electrical power system 100 such that subcircuits contain groups of grid components that function similarly.

In some implementations, the simulation system can determine boundaries the subcircuits that reduce the amount of time, resources, or both required to simulate the entire electrical power system 100. For example, it may be favorable to group components that require certain simulation parameters into their own subcircuits. For example, passive components, such as resistors, inductors, capacitors, and transformers, can be simulated with phasor type models, which generally tend to complete faster and demand fewer computer resources than time domain type models. Time domain type models can apply to simulating fast-acting phenomena, such as inverters. By isolating components that feature fast-acting phenomena into their own subcircuit, the simulation system can reduce the amount of time and computer resources taken to simulate subcircuits without fast-acting phenomena.

The simulation system can determine the boundaries of the subcircuits based on other factors, such as the number of processing cores available, the relative impedances of components in the electrical power system 100, the cleaving step size, and the presence of decoupling equipment, such as switches, transformers, substations, and DC links. The cleaving step size measures can be equal to the largest simulation step size in the respective subcircuit, pair of neighboring subcircuits, or for the simulation as a whole.

The simulation system can determine to select different subcircuit boundaries for the grid model of the electrical power system 100, as depicted in FIG. 1B. For example, compared to FIG. 1A, FIG. 1B has more subcircuits (E-M) and interfaces 122, and the simulation system has separated some of the components based on the type of simulation parameters the simulation system tends to use for each component. For example, subcircuit B of FIG. 1A contained a neighborhood 106 and a substation 110. The simulation system might need to simulate the neighborhood 106 with a phasor type model, while the simulation system might select to simulate the substation 110 with a time domain type model (e.g., due to a higher likelihood of transient events at the substation 110). If both the neighborhood 106 and substation 110 remain in one subcircuit (e.g., subcircuit B) the simulation system would simulate both the neighborhood 106 and substation 110 using resource intensive transient analysis to obtain accurate results for a transient event at the substation 110. However, by splitting subcircuit B into separate subcircuits G and H, the simulation system can make more efficient use of computational resources and by employing the more resource intensive transient type of simulation on the substation 110 in subcircuit H and the less resource intensive steady state type of simulation on the neighborhood 106 in sub circuit G.

The simulation system can determine where to select boundaries between subcircuits based on propagation delays between the subcircuits. For example, drawing certain subcircuit boundaries can take advantage of the physical propagation delay between distant components. In other words, if a propagation delay between two potential subcircuits is greater than the simulation step size of each subcircuit, then the simulation system can simulate one subcircuit without knowledge of the other for a period of time.

The simulation system can partition the grid model of the electrical power system 100 into subcircuits based on the time step size of each subcircuits and propagation delays between potential subcircuits. For example, neighborhood 106 and substation 110 are located a physical distance apart in space that will result in a propagation delay between them when they are in separate subcircuits G and H, as in FIG. 1B. However, if the propagation delay between neighborhood 106 and substation 110 is less than both of the time step sizes used in subcircuits G and H, then the simulations of subcircuits G and H might yield inaccurate results. As a result, the simulation system might determine to draw subcircuit B of FIG. 1A for neighborhood 106 and substation 110, using the same time step sizes. Additionally or alternatively, the simulation system can determine to reduce the time step size of each subcircuit G and H and draw the boundaries of subcircuits G and H. This type of determination can be generalized to more than two subcircuits and more than two components in the electrical power system 100. In general, the further apart two subcircuits are in space, the longer the simulation of one can run without knowledge of the other.

In operation, the simulation system can employ an actor-based model, where the behavior of each subcircuit is simulated as an individual actor and responds to messages received from other subcircuits. A subcircuit behaving like an individual actor can include, but is not limited to, determining simulation parameters, executing a simulation, determining a simulation time, and determining to send messages to or parsing messages from other subcircuits.

In general, it is understood that the processing cores, not the subcircuits, perform the actions of sending, receiving, and parsing messages and other calculations, such as executing and computing. When a subcircuit is described as doing an action, one can assume the processing core associated with that subcircuit actually performs the operations that result in the action being completed.

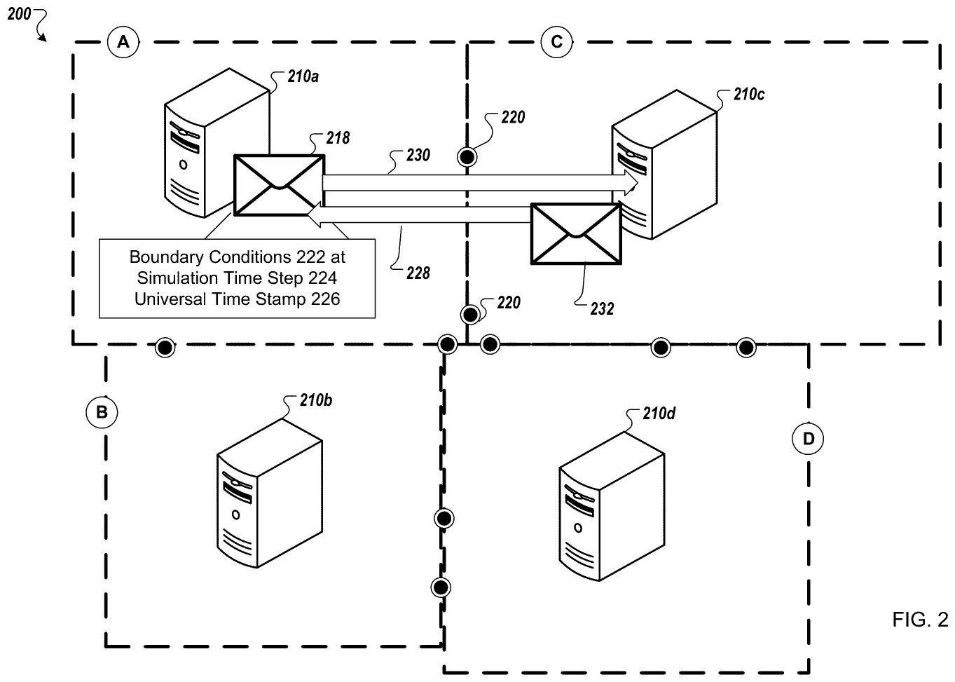

FIG. 2 shows an example messaging system 200 that allows processing cores 210a, 210b, 210c, and 210d, which are simulating subcircuits A, B, C, and D, to communicate. Processing cores 210a, 210b, 210c, and 210d, execute simulations of subcircuits A, B, C, and D, respectively. Processing cores 210a, 210b, 210c, and 210d can communicate boundary conditions of their respective subcircuits A, B, C, and D by sending messages to processing cores with neighboring subcircuits. For example, the simulation system can send a message 218 from subcircuit A to subcircuit C. The message 218 can include boundary conditions 222 for the interfaces 220 between subcircuits A and C. The boundary conditions 222 can include the current and voltage at interfaces 220 at the simulation time step 224 in subcircuit A. Additionally, the messages 218 can include a simulation time step 224 that indicates the time of the boundary conditions 222. For example, a processing core 210a can calculate the current and voltage in subcircuit A for the year 2009, the simulation time step 224 indicating the year 2009, while actually running in in the year 2022.

The simulation system can determine time, e.g., the time in a simulation or “real-world” time in various ways. In some implementations, a processing core can determine the time after parsing a message 218 for the simulation time step 224 and the simulation time step size, e.g., calculating the product of the simulation time step 224 and the time step size. In some implementations, when the various subcircuits have multiple, different simulation time step sizes, a message can include a universal time stamp 226, which in the previous example would indicate the year 2022. The processing cores that send or receive the message can determine the universal time stamp 226.

For each interface 220, subcircuit A can have an incoming queue 228 and outgoing queue 230. One incoming queue 228 includes all of the messages coming from neighboring subcircuits for a given interface 220. For example, each of the two interfaces 220 between subcircuit A and C will have an incoming queue 228 for messages to subcircuit A from subcircuit C, with messages including boundary conditions at the interfaces 220. For interfaces 220 between subcircuits A and C, the outgoing queues 230 include all of the messages going from subcircuit A to neighboring subcircuits C. For example, each of the two interfaces 220 between subcircuit A and C will have an outgoing queue 230 for messages from subcircuit A to subcircuit C. Both message 218 in the outgoing queue and message 232 in the incoming queue can include boundary conditions at the interfaces 220.

In some implementations, the simulation system can send messages between non-neighboring subcircuits. For example, the simulation system could optionally send messages between subcircuits B and C to achieve performance optimization.

In response to receiving a message 218 with boundary conditions 222, subcircuit C can react in various ways, depending on the type of actor model the simulation system has employed. For example, the processing cores can execute their respective simulations of subcircuit in coordination with each other. In an example with two processing cores 210a and 210c simulating a first and second subcircuit respectively (subcircuit A and C), a first processing core 210a can complete a simulation of the first subcircuit A up until a simulation time step tₙ 224. The second processing core 210c can send a message 232 that includes boundary conditions for the interfaces 220 between the first and second subcircuits A and C at simulation time step tₙ. In response to receiving the message 232 that includes boundary conditions for the interfaces 220 between the first and second subcircuits A and C at simulation time step tₙ, the first processing core 210a can execute simulation of the next simulation time step, e.g., tₙ₊₁, of the first subcircuit A and apply the received boundary conditions. Optionally, the first processing core 210a can send a message 218 indicating the boundary conditions 222 for the interfaces 220 between the first and second subcircuits A and C at the simulation time step tₙ.

The previous example can be generalized to more than two processing cores and two subcircuits. For example, a particular subcircuit A could have three neighboring subcircuits B, C, and D. In such an example, the processing core 210a associated with the particular subcircuit A could receive multiple messages from its three neighbor subcircuits B, C, D that include boundary conditions for all the interfaces between the particular subcircuit A and its neighboring subcircuits B, C, and D. In response to receiving the multiple messages that include boundary conditions the interfaces between particular subcircuit A and its neighboring subcircuits B, C, and D at simulation time step tₙ, the particular processing core 210a can execute simulation of the next simulation time step, e.g., tₙ₊₁, of the particular subcircuit A.

In some implementations, subcircuits A, B, C, and D can use different time step sizes in their respective simulations. For example, the time step size Δt_{A} in the simulation of the particular subcircuit A can be less than the time step size used to simulate neighboring subcircuit C. In some implementations, the simulation of subcircuit A can proceed even if the simulation time in subcircuit A is less than the simulation time in a message from its neighboring subcircuit C. For example, a first subcircuit A could simulate at a time step size, e.g., time resolution, of Δt_{A}=50 ms. Subcircuit C can simulate at time step size of Δt_{C}=1 s. In this example, the first processing core 210a can receive a message 228 from the second processing core 210c with boundary conditions at the interface 220 between the first and second subcircuit A and C with the simulation time of time_{B}=3 s, while the simulation time in first subcircuit A is time_{A}=3400 ms=3.4 s. Even though time_{A}>time_{C}, the simulation of subcircuit A can proceed, since it doesn't need input from subcircuit C until the simulation time step after time_{C}=3 s, e.g., time_{C}=4 s.

In some implementations, predictive algorithms or extrapolation can allow an individual subcircuit to advance in the simulation before it has received messages from its neighboring subcircuits with an appropriate simulation time or simulation time step. For example, a first processing core 210a can complete a simulation of the particular subcircuit A up until a particular simulation time step (t_{n,A}) of the simulation or a particular simulation time. The simulation time can be defined as time_{n,x}=t_{n,x}×Δtₓ for a particular subcircuit X. The first processing core 210a can determine that it has not received messages from a second processing core 210c simulating a second subcircuit C, which neighbors the first subcircuit, with boundary conditions relevant to simulation time step t_{n,A} (e.g., or time_{n,A}). The first processing core 210a can estimate output values of the second subcircuit C at simulation time step t_{n,C} (e.g., or time_{n,C}) based on extrapolation from values from messages 232 sent from the second subcircuit C with boundary conditions for one or more prior simulation time steps (e.g., tₙ₋₁,c) or at one or more prior simulation times (e.g., time_{n,C}−Δt_{C}, where Δt_{C} is a time step size in subcircuit C). Then the first processing core 210a can execute simulation of the first subcircuit for the next simulation time step (e.g., t_{n+1,A}), using the estimated boundary conditions. In some cases, an estimated boundary value from a neighboring subcircuit at simulation time step t_{n,C} may disagree with the actual values, e.g., the boundary values at the interfaces that the processing cores associated with neighboring subcircuit C eventually calculates and sends in a message. In such cases, the first processing core 210a can compute a correction factor for the simulation output based on estimated boundary conditions of subcircuit A at simulation time step t_{n+1,A} and adjust the simulated output. In some implementations, the first processing core 210a can re-execute simulation of the first subcircuit A for simulation time step t_{n+1,A} using the boundary conditions received from the neighboring subcircuit C at simulation time step t_{n,C}.

Computing the correction factor can include determining if the difference between the processing core 210's estimated boundary conditions of the neighboring subcircuit C at simulation time step tₙ disagree with the boundary conditions received from processing core 210c for the simulation of subcircuit C for simulation time step tₙ outside a threshold value, e.g., above or below a certain number. For example, if the boundary condition values agreed within the threshold value, the processing core 210a does not need to compute a correction factor or re-execute simulation of the first subcircuit A for simulation time step tₙ₊₁. If the two values disagree outside the threshold value, the processing core 210a can compute a correction factor that depends on the two boundary condition values. For example, the processing core 210a can compute a correction factor and adjust its simulated output of subcircuit A for the particular simulation time step tₙ₊₁ or re-execute simulation of subcircuit A for the particular simulation time step tₙ₊₁ depending on how great the disagreement is between the estimated and actual boundary conditions.

The simulation system can compute the correction factor based on the time step size Δt of each subcircuit. For example, the simulation system can weight the boundary condition values in the correction factor, with boundary conditions from subcircuits with finer time step size Δt being weighed more heavily. In some implementations, if the time step sizes Δt are different enough, e.g., Δt_{A}>>Δt_{C}, computing the correction factor can include disregarding the estimated output values from subcircuit A and storing the boundary conditions for interfaces 220 that the processing core 210c associated with neighboring subcircuit C eventually calculated.

In some implementations, using a default course time step size, e.g., resolution, for the simulation the subcircuits A, B, C, and D can reduce the overall time of the simulation. For example, multiple processing cores associated with multiple subcircuits could use a coarse default time resolution, e.g., 1 second. A particular processing core 210a can identify a transient in its associated, particular subcircuit A at a particular simulation time step (e.g., simulation time step tₙ). The particular processing core 210a can lower the time step size to a finer time step size, e. g, milliseconds, and continue the simulation of the particular subcircuit A at the finer time step size for simulation time steps subsequent to simulation time step tₙ, e.g., tₙ₊₁. The particular processing core 210a can send a message 218 to other processing cores (e.g., those simulating neighboring subcircuits) indicating that the particular processing core 210a is simulating a transient for its respective subcircuit and is executing the simulation at a time resolution less than the default time resolution.

In some implementations, each processing core 210a, 210b, 210c, and 210d stores data indicating the time step size in neighboring subcircuits, e.g., subcircuits with interfaces. In such implementations, the processing core (e.g., processing core 210a) can send boundary conditions to the processing cores simulating subcircuit A's neighbors in synchronization with the respective simulation time step sizes of the neighboring subcircuit. For example, if neighboring subcircuit C has a time step size Δt_{C}=1 s, and neighboring subcircuit B has a time step size Δt_{B}=0.5 s, processing core 210a can send boundary conditions 222 in messages 218 to processing core 210c every second, and send boundary condition messages to processing core 210b every 0.5 s.

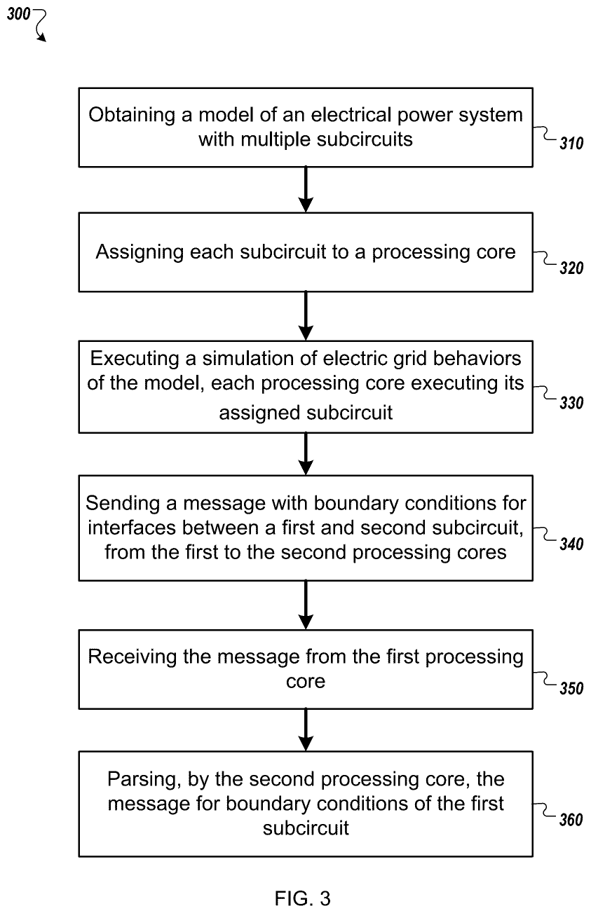

FIG. 3 shows an example process 300 for a simulation system simulating an electrical power grid. A simulation system can perform the process 300, using the grid model of the electrical power system 100 as an example. A simulation system can obtain a model of an electrical power system 100 with multiple subcircuits A, B, C, and D (310). The simulation system can obtain the model in various ways, such as receiving or downloading the model from a database, or creating the model itself.

In some implementations, the model can include a high resolution electrical model of one or more electrical distribution feeders. The model can include, for example, data models of substation transformers, distribution switches and reclosers, voltage regulation schemes, e.g., tapped magnetics or switched capacitors, network transformers, load transformers, inverters, generators, and various loads. The model can include line models, e.g., electrical models of medium voltage distribution lines. The model can also include electrical models of fixed and switched line capacitors, as well as other grid components and equipment.

The model can include a topological representation of a power grid or a portion of the power grid. The detail of the model can be sufficient to allow for accurate simulation and representation of steady-state, dynamic and transient operation of the grid.

The model can include different versions of the same electrical grid. Each version may represent the past, the present and the future states of the grid, including changes of topology over time such as introduction of new assets and changing of switch positions. This enables analyzing past behavior as well as series of planned or hypothetical scenarios. Different versions of the model can represent the intended grid design, the as-built design, the operational design, and future versions that represent combinations of planned and hypothetical equipment modifications, additions, removals, and replacements.

The model can take into account the interdependency of energy systems beyond the electrical grid, such as the electrical elements of a natural gas storage, distribution and electrical generation system. The model can represent interactions between the two systems. Backup power systems interacting with primary power systems is another example, particularly for battery and solar powered systems that may replace diesel generator systems. Detailed models of all interacting subsystems with associated simulations of all normal, abnormal, and corner conditions can be performed.

The model can be calibrated by using measured electrical power grid data. The measured electrical power grid data can include historical grid operating data. The historical grid operating data can be collected during grid operation over a period of time, e.g., a number of weeks, months, or years. In some examples, the historical grid operating data can be average historical operating data. For example, historical grid operating data can include an electrical load on a substation during a particular hour of the year, averaged over multiple years. In another example, historical grid operating data can include a number of voltage violations of the electrical power grid during a particular hour of the year, possibly averaged over multiple years, or otherwise represented statistically.

In some examples, the model can include assumptions. For example, the model can include measured data for certain locations of the power grid, and might not include measured data for other locations. The model can use assumptions to interpolate grid operating data for locations in which measurements are not available. An assumption can be, for example, an assumed ratio or relationship between loads at industrial locations of the power grid compared to residential locations of the power grid.

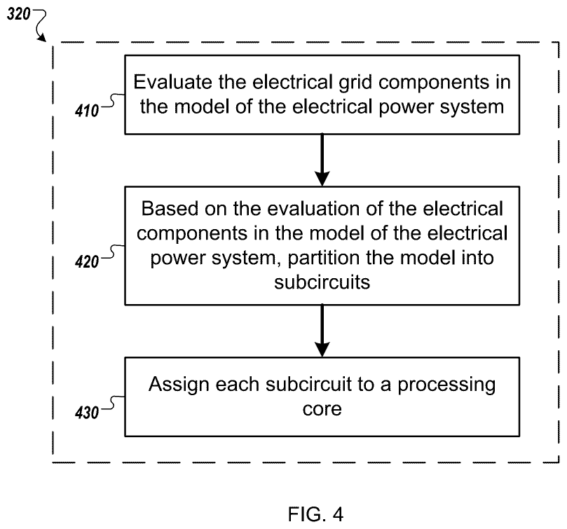

The simulation system can assign each subcircuit A, B, C, and D to a processing core 210a, 210b, 210c, and 210d (320). The assignment can depend on factors including, but not limited to, propagation delays, distances between processing cores, signal delays between the processing cores, the number of subcircuits and processing cores, the size of subcircuits, and the processing capacity of the processing cores. For example, as discussed in more detail in reference to FIG. 4, the simulation system can divide select subcircuits based on a combination of simulation step size (e.g., time resolution) and propagation delay between subcircuits. Once divided, each subcircuit can be assigned to a particular processing core. In some implementations, the simulation system can determine to assign more than one subcircuit to a processing core. In some implementations, there are more subcircuits than processing cores, and vice versa.

The processing cores 210a, 210b, 210c, and 210d can execute simulations of electrical grid behaviors of the model, each processing core executing its assigned subcircuit(s) (330). For example, each processing core is capable of executing the described simulations for its respective subcircuit. That is, each processing core can execute a simulation of its assigned subcircuit in parallel (e.g., concurrently) with the others. In some implementations, the simulation system can determine the simulation parameters of each subcircuit A, B, C, and D based on the components 102-120 in each subcircuit. For example, components 102-120 can have different operating parameters or set points that are more relevant for operations in steady state than for operations during transients. For example, a breaker can have a time delay over a current or over a voltage trip that trips the breaker only after a short period of time (fractions of a second). A model can adapt to combine steady state and transient operating parameters for components that indicate which operating parameters or set points are effective in each type of simulation.

The simulation system can simulate steady state and transient electric grid operations, e.g., collectively called “behaviors”, and responses. The processing cores can simulate grid behaviors on different time scales (e.g., different time resolution), and in some case, may employ different mathematical modeling domains. For example, a steady state model can simulate grid behaviors with a simultaneous solution of net energy flow across a grid to calculate various grid operational parameters (e.g., voltages and currents) at various locations throughout the grid for each simulation time step. In some implementations, a steady state simulation uses iterative methods to converge on a steady-state solution for the operational parameters. On the other hand, a transient simulation is used to simulate transient and dynamic behaviors of grid components and electrical systems as evolving over time. A transient simulation can include a wide range of possible time resolutions (e. g. ranging from minutes to nanoseconds) and calculate operational parameters using time-domain methods that produce time-series of electrical quantities such as voltage, current, real and reactive power, etc.

The simulation system can simulate a distribution of voltage and current values by treating the simulation as a stochastic process. Each simulation step can sample from provided distributions of electrical properties, load, and generation. Running many of these simulations enables estimating a distribution over the outcomes and defining confidence intervals around the predicted behavior.

A first processing core can send a message with boundary conditions for interfaces between the first and second subcircuit, the message going from the first to the second processing cores, e.g., from subcircuit A to C of FIG. 2 (340). The boundary conditions 222 can include the current and voltage at the simulation time in subcircuit A for interfaces 220 between subcircuits A and C. For example, a transmission line can cross the boundary between subcircuits A and C. The message 218 can include the current and voltage of the interface 220 where the transmission line intersects the boundary of the subcircuit A, calculated by the first processing core 210a. To arrive at the second processing core 210c, the message 218 can leave an outgoing queue 230 associated with the interface 220 for subcircuit A. Then the message 218 can arrive at an incoming queue associated with the interface 220 for subcircuit C.

The second processing core 210c can receive, from the first processing core 210a, the message (350). In some implementations, the message 218 arrives at the first processing core in an incoming queue 228.

The second processing core 210c can parse the message 218 for boundary conditions 222 of subcircuit A (360). The parsed boundary conditions can include boundary conditions 222, such as the current and voltage for the interfaces 220 at simulation time step 224 between subcircuits A and C. In some implementations, the second processing core 210c can parse the message for a simulation time step 224 or information about the subcircuit to extract the boundary conditions contained therein. The second processing core 210c can then execute simulation of a subsequent time step based on the extracted boundary conditions. For example, the second processing core 210c can simulate behaviors of subcircuit C during the subsequent simulation time step using by applying the boundary condition values as simulation input/initial conditions at its interface with subcircuit A.

In some implementations, the process 300 can include additional steps, fewer steps, or some of the steps can be divided into multiple steps. In some implementations, step 340 and 350 can repeat multiple times before step 360. For example, a first processing core can send multiple messages with boundary conditions to the second processing core before the second processing core parses the first message of the multiple messages. In such implementations, the second processing core can wait a predetermined amount of time before parsing the messages from the first processing core. The predetermined amount of time can depend on the propagation delay between the first and second processing cores and the step size of the simulation of the first processing core. For example, the second processing core wait until it has received ten messages from the first processing core if the propagation delay between the subcircuits A and B is ten times the step size of the simulation in subcircuit A. Waiting can be advantageous, as it can reduce an amount of processing power the second processing core expends in updating the boundary conditions of the simulation in response to parsing the messages.

In some implementations, the simulation system can perform multiple actions between steps 340 and 350. For example, each processing core can determine to de-queue a message in the incoming queue before parsing the message. Determining to de-queue a message can include determining whether the second processing core can advance in the simulation of the second subcircuit without knowledge of the boundary conditions of neighboring subcircuits. Depending on the type of actor model employed by the simulation system, the second processing core respond to receiving the message in various ways, as discussed earlier. In some implementations, after the second processing core parses the message, the two processing cores associated with each subcircuit can “sync up,” e.g., set the boundary conditions at the interfaces between the two subcircuits to be substantially equal, advance in each simulation starting at same simulation time, or both.

Additionally, step 320 can include partitioning the electrical power system into multiple subcircuits. FIG. 4 shows the process 400 for assigning the subcircuits to processing cores, which step 320 can include. The simulation system can evaluate the electrical grid components in the model of the electrical power system 100 (410). Evaluating can include determining the electrical characteristics of each component, such as, but not limited to the resistance, capacitance, impedance, inductance, power capacity, and typical electrical behaviors. The simulation system can store, for each component, standard simulation parameters that reflect the electrical characteristics. For example, a power station might regularly feature fast-acting electrical phenomena, and the simulation system can access the simulation parameters that are generally used for transient phenomena. As another example, the simulation system can compare the relative impedances of every component in the electrical power system 100. Evaluating the components in the electrical power system 100 can also include determining their geographic location in the model.

Based on the evaluation of the electrical grid components in the model of the electrical power system 100, the simulation system can partition the model of the electrical power system into subcircuits (420). In some implementations, partitioning the model can depend on factors that include, but are not limited to, propagation delays that would arise between the possible subcircuits and the time step sizes associated with electrical grid components in the possible subcircuits. In some implementations, user input can indicate factors, such as maximum duration of the simulation or desired numerical precision, to optimize for time, accuracy, or both. In some implementations, partitioning can depend on the number and processing capacity of the available processing cores, the proximity of the available processing cores relative to one other, the communication lag between available processing cores, and the type of grid components in the simulation, e.g., whether the grid components cause decoupling behavior.

The simulation system can assign each subcircuit, e.g., subcircuits A, B, C, and D to a processing core, e.g., processing cores 210a, 210b, 210c, and 210d (430). In some implementations, a processing core can have multiple assigned subcircuits. The assigning can depend on factors such as, but not limited to, the number of available processing cores, the processing capacity of each processing core, the simulation parameters associated with the electrical grid components in each subcircuit, the size of each subcircuits, the propagation delay between each subcircuit, and the physical location of each processing core.

This disclosure generally describes computer-implemented methods, software, and systems for electrical power grid visualization. A computing system can receive various electrical power grid data from multiple sources. Power grid data can include different temporal and spatially dependent characteristics of a power grid. The characteristics can include, for example, power flow, voltage, power factor, feeder utilization, and transformer utilization. These characteristics can be coupled; for example, some characteristics may influence others and/or their temporal and spatial dependence may be related.

Data sources can include satellites, aerial image databases, publicly available government power grid databases, and utility provider databases. The sources can also include sensors installed within the electrical grid by the grid operator or by others, e.g., power meters, current meters, voltage meters, or other devices with sensing capabilities that are connected to the power grid. Data sources can include databases and sensors for both high voltage transmission and medium voltage distribution and low voltage utilization systems.

The data can include, but is not limited to, map data, transformer locations and capacities, feeder locations and capacities, load locations, or a combination thereof. The data can also include measured data from various points of the electrical grid, e.g., voltage, power, current, power factor, phase, and phase balance between lines. In some examples, the data can include historical measured power grid data. In some examples, the data can include real-time measured power grid data. In some examples, the data can include simulated data. In some examples, the data can include a combination of measured and simulated data.

Implementations of the subject matter and the functional operations described in this specification can be implemented in digital electronic circuitry, in tangibly-implemented computer software or firmware, in computer hardware, including the structures disclosed in this specification and their structural equivalents, or in combinations of one or more of them. Implementations of the subject matter described in this specification can be implemented as one or more computer programs, i.e., one or more modules of computer program instructions encoded on a tangible non-transitory program carrier for execution by, or to control the operation of, data processing apparatus. The computer storage medium can be a machine-readable storage device, a machine-readable storage substrate, a random or serial access memory device, or a combination of one or more of them.

The term “data processing apparatus” refers to data processing hardware and encompasses all kinds of apparatus, devices, and machines for processing data, including, by way of example, a programmable processor, a computer, or multiple processors or computers. The apparatus can also be or further include special purpose logic circuitry, e.g., a central processing unit (CPU), a FPGA (field programmable gate array), or an ASIC (application-specific integrated circuit). In some implementations, the data processing apparatus and/or special purpose logic circuitry may be hardware-based and/or software-based. The apparatus can optionally include code that creates an execution environment for computer programs, e.g., code that constitutes processor firmware, a protocol stack, a database management system, an operating system, or a combination of one or more of them. The present disclosure contemplates the use of data processing apparatuses with or without conventional operating systems, for example Linux, UNIX, Windows, Mac OS, Android, iOS or any other suitable conventional operating system.

A computer program, which may also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, subroutine, or other unit suitable for use in a computing environment. A computer program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a communication network. While portions of the programs illustrated in the various figures are shown as individual modules that implement the various features and functionality through various objects, methods, or other processes, the programs may instead include a number of sub-modules, third party services, components, libraries, and such, as appropriate. Conversely, the features and functionality of various components can be combined into single components as appropriate.

The processes and logic flows described in this specification can be performed by one or more programmable computers executing one or more computer programs to perform functions by operating on input data and generating output. The processes and logic flows can also be performed by, and apparatus can also be implemented as, special purpose logic circuitry, e.g., a central processing unit (CPU), a FPGA (field programmable gate array), or an ASIC (application-specific integrated circuit).

Computers suitable for the execution of a computer program include, by way of example, can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer-readable media (transitory or non-transitory, as appropriate) suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The memory may store various objects or data, including caches, classes, frameworks, applications, backup data, jobs, web pages, web page templates, database tables, repositories storing business and/or dynamic information, and any other appropriate information including any parameters, variables, algorithms, instructions, rules, constraints, or references thereto. Additionally, the memory may include any other appropriate data, such as logs, policies, security or access data, reporting files, as well as others. The processor and the memory can be supplemented by, or incorporated in, special purpose logic circuitry.

To provide for interaction with a user, implementations of the subject matter described in this specification can be implemented on a computer having a display device, e.g., a CRT (cathode ray tube), LCD (liquid crystal display), or plasma monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

The term “graphical user interface,” or GUI, may be used in the singular or the plural to describe one or more graphical user interfaces and each of the displays of a particular graphical user interface. Therefore, a GUI may represent any graphical user interface, including but not limited to, a web browser, a touch screen, or a command line interface (CLI) that processes information and efficiently presents the information results to the user. In general, a GUI may include a plurality of user interface (UI) elements, some or all associated with a web browser, such as interactive fields, pull-down lists, and buttons operable by the business suite user. These and other UI elements may be related to or represent the functions of the web browser.

Implementations of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN), a wide area network (WAN), e.g., the Internet, and a wireless local area network (WLAN).

The computing system can include clients and servers. A client and server are generally remote from each other and typically interact through a communication network. The relationship of client and server arises by virtue of computer programs running on the respective computers and having a client-server relationship to each other.

While this specification contains many specific implementation details, these should not be construed as limitations on the scope of any system or on the scope of what may be claimed, but rather as descriptions of features that may be specific to particular implementations of particular systems. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of sub-combinations.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be helpful. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations, alterations, and permutations of the described implementations are within the scope of the following claims as will be apparent to those skilled in the art.

For example, the actions recited in the claims can be performed in a different order and still achieve desirable results.

Accordingly, the above description of example implementations does not define or constrain this disclosure. Other changes, substitutions, and alterations are also possible without departing from the spirit and scope of this disclosure.

What is claimed is:

1. An electrical system simulation method comprising:
obtaining a model of an electrical system comprising a plurality of subcircuits;
assigning each of the plurality of subcircuits to a processing core from among a plurality of processing cores employed for simulation of the model;
executing a simulation of behaviors of the model, wherein the simulation of each subcircuit is executed by the respective processing core assigned to the subcircuit; and
sending a message, from a first processing core assigned to a first subcircuit to a second processing core assigned to a second subcircuit, the message comprising one or more boundary conditions at an interface between the first subcircuit and the second subcircuit in the model.

2. The method of claim 1, further comprising:
evaluating one or more electrical components in the model of the electrical system; and
based on the evaluation of the one or more electrical components in the model of the electrical system, partitioning the model into the plurality of subcircuits.

3. The method of claim 2, further comprising:
determining one or more propagation delays between the plurality of subcircuits; and
wherein partitioning the model into the plurality of subcircuits is further based on the one or more propagation delays between the plurality of subcircuits.

4. The method of claim 3, wherein evaluating one or more electrical grid components in the model of the electrical system comprises determining a simulation time step size associated with one or more of the electrical grid components in the model of the electrical power system.

5. The method of claim 1, wherein executing the simulation of electric grid behaviors of the model comprises:
executing the simulation of the first subcircuit on by the first processing core according to a first set of simulation parameters; and
executing the simulation of the second subcircuit on the second processing core according to a second, different set of simulation parameters.

6. The method of claim 5, wherein the first set of simulation parameters comprise a first simulation time step size and the second set of simulation parameters comprise a second, different simulation time step size.

7. The method of claim 1, wherein the one or more boundary conditions of the first subcircuit include simulation output, generated by the first processing core, for electrical conditions at the interface.

8. The method of claim 7, wherein the electrical conditions include one or more of: a current value at the interface, a voltage value at the interface, a simulation time step at which the current and voltage values were simulated, and a propagation delay between the first subcircuit and the second subcircuit.

9. The method of claim 1, wherein executing a simulation of the behaviors of the model comprises:
completing a simulation of the first subcircuit up until a simulation time step tₙ, wherein the message comprises boundary conditions at the interface between the first subcircuit and the second subcircuit at simulation time step tₙ; and
in response to receiving the message, executing, by the second processing core, simulation of electric grid behaviors of the model in the second subcircuit for simulation time step tₙ₊₁.

10. The method of claim 1, wherein each subcircuit of the plurality of subcircuits has a default time step size, the method further comprising:
identifying a transient behavior in the first subcircuit at a simulation time step tₙ;
reducing, by the first processor, a time step size of the first subcircuit to less than the default time step size; and
continuing to execute simulation of the first subcircuit with the reduced time step size and the second subcircuit with the default time step size for simulation time steps greater than simulation time step tₙ.

11. The method of claim 10, further comprising:
sending, to the second processing core, a second message, indicating boundary conditions at the interface between the first subcircuit and the second subcircuit and an indication that a time step size in the first subcircuit is less than a default time step size, at a simulation time step tₙ₊₁ greater than the simulation time step tₙ; and
receiving, from the first processing core, the second message.

12. The method of claim 11, further comprising:
calculating, by the second processing core, values for the interface at the simulation time step tₙ₊₁;
in response to receiving the second message, determining, by the first processing core, that the second message comprises values for the boundary conditions at the interface that disagree with the calculated values outside a threshold value; and
calculating, by the second processing core, a correction factor for simulation of the second subcircuit for the simulation time step tₙ₊₁.

13. The method of claim 12, further comprising, in response to determining that the second message comprises values that disagree with the calculated values outside a threshold value, reducing a time step size of the second subcircuit.

14. The method of claim 1, wherein executing a simulation of the behaviors of the model comprises:
completing a simulation of the first subcircuit up until a simulation time step tₙ₋₁, wherein the message comprises boundary conditions at the interface at the simulation time step tₙ₋₁;
in response to receiving the message comprising the simulation time step tₙ₋₁, estimating, by the second processing core, values for the boundary conditions at the interface at a simulation time step tₙ in the first subcircuit; and
continuing to execute, using the estimated values, simulation the first subcircuit for simulation time steps greater that tₙ.

15. A system comprising:
at least one processor; and a data store coupled to the at least one processor having instructions stored thereon which, when executed by the at least one processor, causes the at least one processor to perform operations comprising:
obtaining a model of an electrical system comprising a plurality of subcircuits;
assigning each of the plurality of subcircuits to a processing core from among a plurality of processing cores employed for simulation of the model;
executing a simulation of behaviors of the model, wherein the simulation of each subcircuit is executed by the respective processing core assigned to the subcircuit; and
sending a message, from a first processing core assigned to a first subcircuit to a second processing core assigned to a second subcircuit, the message comprising one or more boundary conditions at an interface between the first subcircuit and the second subcircuit in the model.

16. The system of claim 15, the operations further comprising:
evaluating one or more electrical components in the model of the electrical system; and
based on the evaluation of the one or more electrical components in the model of the electrical system, partitioning the model into the plurality of subcircuits.

17. The system of claim 16, the operations further comprising:
determining one or more propagation delays between the plurality of subcircuits; and
wherein partitioning the model into the plurality of subcircuits is further based on the one or more propagation delays between the plurality of subcircuits.

18. The system of claim 17, wherein evaluating one or more electrical grid components in the model of the electrical system comprises determining a simulation time step size associated with one or more of the electrical grid components in the model of the electrical power system.

19. The system of claim 15, wherein executing the simulation of electric grid behaviors of the model comprises:
executing the simulation of the first subcircuit on by the first processing core according to a first set of simulation parameters; and
executing the simulation of the second subcircuit on the second processing core according to a second, different set of simulation parameters.

20. A non-transitory computer readable storage medium storing instructions that, when executed by at least one processor, cause the at least one processor to perform operations comprising:
obtaining a model of an electrical system comprising a plurality of subcircuits;
assigning each of the plurality of subcircuits to a processing core from among a plurality of processing cores employed for simulation of the model;
executing a simulation of behaviors of the model, wherein the simulation of each subcircuit is executed by the respective processing core assigned to the subcircuit; and
sending a message, from a first processing core assigned to a first subcircuit to a second processing core assigned to a second subcircuit, the message comprising one or more boundary conditions at an interface between the first subcircuit and the second subcircuit in the model.
